(19) United States
(12) Patent Application Publication
(10) Pub. No.: US 2026/0231392 A1
(43) Pub. Date: Aug. 6, 2026

(54) MANUFACTURING METHOD OF MEMORY DEVICE

(71) Applicant: NANYA TECHNOLOGY CORPORATION, New Taipei City (TW)

(72) Inventor: Min Chung Cheng, New Taipei City (TW)

(73) Assignee: NANYA TECHNOLOGY CORPORATION, New Taipei City (TW)

(21) Appl. No.: 19/046,548

(22) Filed: Feb. 6, 2025

(51) Int. Cl. H10B 12/00

(52) U.S. Cl. CPC H10B 12/033

(57) ABSTRACT

A manufacturing method of a memory device including: forming a landing pad over a substrate; forming a first insulating structure over the substrate and the landing pad; forming a patterned mask layer over the insulating structure; removing portions of the first insulating structure by the patterned mask layer to form a container exposing the landing pad; forming an electrode structure over the substrate, wherein the electrode structure comprises a first portion disposed on the patterned mask layer and a second portion disposed in the container; removing the first portion of the electrode structure by a first etching back process; removing the patterned mask layer by a second etching back process to form recesses on the first insulating structure and beside the second portion of the electrode structure; and forming a second insulating structure in the recesses.

### BACKGROUND

### Technical Field

The present disclosure relates to a manufacturing method of a memory device.

### Description of Related Art

For continuous advancements in technology, a height and a width of a storage electrode of a capacitor will affect performance of the memory device. For example, high-aspect-ratio (AR) of the capacitor has cost and quality issues.

### SUMMARY

The disclosure provides a manufacturing method of a memory device including: forming a landing pad over a substrate; forming a first insulating structure over the substrate and the landing pad; forming a patterned mask layer over the insulating structure; removing portions of the first insulating structure by the patterned mask layer to form a container exposing the landing pad; forming an electrode structure comprising a first portion disposed on the patterned mask layer and a second portion disposed in the container; removing the first portion of the electrode structure by a first etching back process; removing the patterned mask layer by a second etching back process to form recesses on the first insulating structure and beside the second portion of the electrode structure; and forming a second insulating structure in the recesses.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a flow diagram of some embodiments of intermediate steps of a manufacturing method of a memory device.

FIG. 2 to FIG. 9 are cross-sectional views illustrating portions of a manufacturing method of a memory device according to an embodiment of the disclosure.

FIG. 10 is cross-sectional views illustrating portions of a memory device according to an alternative embodiment of the disclosure.

### DESCRIPTION OF THE EMBODIMENTS

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

Performance of the memory device may involve in each capacitor within the cell. For example, A storage electrode of the capacitor of the memory device is shaped as a container, and the advancements in technology are resulting in increasing a height and decreasing a width of container-shaped storage nodes. Here, the height of container may be formed by various insulating films (such as at least five insulating layers stacked to each other). However, high-aspect-ratio may come with aforementioned design, such that manufacturing cost may be raised. For example, etching technique for high-aspect-ratio is very expensive, such as high purchasing cost of precision photolithography apparatuses. In addition, quality of the container may be reduced when a desired height of the container is achieved by once etching process (etching too deeper). In the present disclosure, the issue of the high-aspect-ratio may be improved by reducing the height of the container at first and performing the etching back process and backfill another insulating layer to remedy other portions of the desired height.

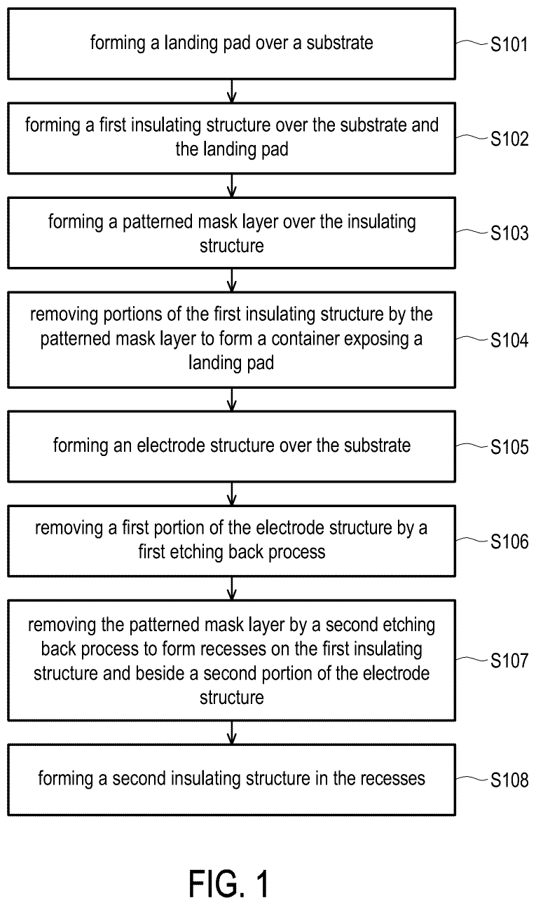

FIG. 1 is a flow diagram illustrating intermediate steps of a method of manufacturing a memory device in accordance with some embodiments of the present disclosure. The method includes a number of operations (S101, S102, S103, S104, S105, S106, S107, and S108). The description and illustration are not deemed as a limitation to the sequence of the operations.

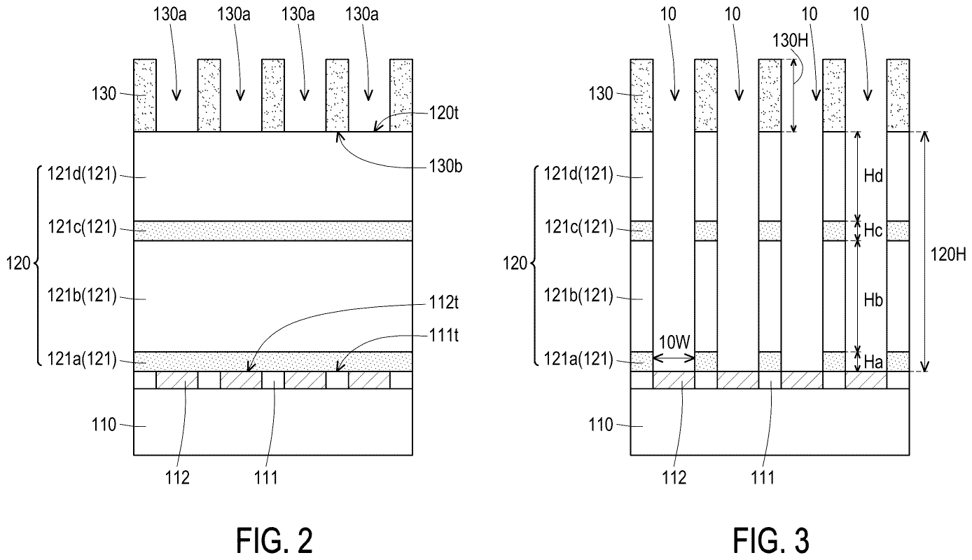

At block 101, form a landing pad over a substrate. At block 102, form a first insulating structure over the substrate and the landing pad. At block 103, form a patterned mask layer over the insulating structure. FIG. 2 illustrates a cross-sectional view of some embodiments corresponding to blocks 101, 102, 103.

In FIG. 2, a substrate 110 is provided. In some embodiments, the substrate 110 is a semiconductor substrate, such as a bulk semiconductor, a semiconductor-on-insulator (SOI) substrate, or the like. In some embodiments, the substrate 110 include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of silicon, SiGe, GaAsP, AlInAs, AlGaAs, GaInAs, GaInP, and GaInAsP; any other suitable materials; or a combination thereof. In some embodiments, the alloy semiconductor substrate may be a silicon alloy with a gradient silicon feature in which Si and metal compositions change from one ratio at one location to another ratio at another location of the gradient silicon feature. For example, the alloy semiconductor substrate may be a SiGe alloy with a gradient SiGe feature in which Si and Ge compositions change from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy.

Further, an isolation layer 111 and a plurality of landing pads 112 are formed over the substrate 110, wherein the landing pads 112 are embedded in the isolation layer 111 to keep better electrical performance. In some embodiments, a chemical mechanical planarization (CMP) operation may be performed from above the isolation layer 111 and the landing pads 112, such that a top surface 111t of the isolation layer 111 and top surfaces 112t of the landing pads 112 are substantially coplanar. In some embodiments, the isolation layer 111 include suitable insulating materials and the landing pads 112 include suitable conductive materials.

And then, an insulating structure 120 (may be referred to first insulating structure) is formed over the substrate 110 and extends over the top surface 111t of the isolation layer 111 and the top surfaces 112t of the landing pads 112. The materials of the insulating structure 120 include nitride or oxide, such as silicon nitride (SiN), BPSG. TEOS, or the like. After forming the insulating structure 120, a patterned mask layer 130 is formed over the insulating structure 120 for subsequent process (such as etching process). In the embodiment, a top surface 120t of the first insulating structure 120 is in direct contact with a bottom surface 130b of the patterned mask layer 130. Moreover, the patterned mask layer 130 may include a plurality of openings 130a to expose portions of the top surface 120t of the insulating structure 120 which directly overlying the landing pads 112. In some embodiments, materials of the patterned mask layer 130 include polysilicon. Here, the insulating structure 120 and the patterned mask layer 130 may be form by suitable deposition processes, such as blanket deposition, chemical vapor deposition (CVD), physical vapor deposition (PVD), atomic layer deposition (ALD), or the like.

As used herein, the terms “patterned” are used in the present disclosure to describe an operation of forming a predetermined pattern on a surface. The patterning operation includes various steps and processes and varies in accordance with different embodiments. In some embodiments, a patterning process is adopted to pattern an existing film or layer (such as polysilicon). The patterning process includes forming a mask on the existing film or layer and removing the unmasked film or layer with an etching or other removal process. The mask can be a photoresist or a hard mask.

At block 104, remove portions of the first insulating structure by the patterned mask layer to form a container exposing a landing pad. FIG. 2 to FIG. 3 illustrate cross-sectional views of some embodiments corresponding to block 104.

In FIG. 2. the first insulating structure 120 includes four insulating layers 121. For example, a nitride layer 121a (may be referred to first nitride layer), an oxide layer 121b (may be referred to first oxide layer), a nitride layer 121c (may be referred to second nitride layer), and an oxide layer 121d (may be referred to second oxide layer), are stacked on the substrate 110 sequentially. In some embodiments, materials of the nitride layers 121, 123 include silicon nitride (SiN) or the like, and materials of the oxide layer 122, 124 include BPSG. TEOS, or the like. It should be noted that a number of layers (121, 122, 123, and 124) are not deemed as a limitation to the disclosure, a number of layers of the insulating structure 120 may be determined according to actual design requirements.

In FIG. 3, portions of the first insulating structure 120 is removed by the patterned mask layer 130 to form a plurality of containers 10 exposing the landing pads 112. Here, removing process may be a suitable etching process. In the embodiment, aspect ratio is the ratio of a height 120H of the first insulating structure 120 to a width 10W (such as critical size, CD) of the container 10. For example, four insulating layers 121 of the first insulating structure 120 may replace five insulating layers of the capacitor structure, in other words, the height 120H of the first insulating structure 120 (four insulating layers 121) is less than a height of the capacitor structure (five insulating layers), such that the removed height (such as etching height) may be reduced, thereby the precision photolithography apparatuses may be omitted, and the quality of the container 10 may be increased (etching process completion is better), the issue of the high-aspect-ratio may be improved.

In some embodiments, the height 120H of the first insulating structure 120 ranges between 1000 nm to 1300 nm, the width 10W of the container 10 ranges between 20 nm and 30 nm (e.g. between 20 nm and 24 nm), thereby the aspect ratio of each of the containers 10 ranges between 30 and 40, the aspect ratio of the container 10 may be controlled within a range that is more easier to etch. In the embodiments, since oxide is easier to remove, a height of the oxide layer 121b, 121d are greater than the nitride layer 121a, 121c. For example, a height Ha of the nitride layer 121a ranges between 20 nm and 30 nm, a height Hb of the oxide layer 121b ranges between 5000 Å and 5400 Å, a height Hc of the nitride layer 121c ranges between 20 nm and 30 nm, and a height Hd of the oxide layer 121d ranges between 4000 Å and 4500 Å. On the other hand, a height 130H of the patterned mask layer 130 in step of FIG. 2 ranges between 350 nm and 500 nm, and a height 130H of the patterned mask layer 130 in step of FIG. 3 may become 100 nm and 200 nm, that is to say, portions of the patterned mask layer 130 may be removed in formation process of the container 10. In the embodiment, the width 10W of the container 10 is less than or equal to a width of the landing pad 112, by doing so, impedance is reduced, and electrical performance may be better.

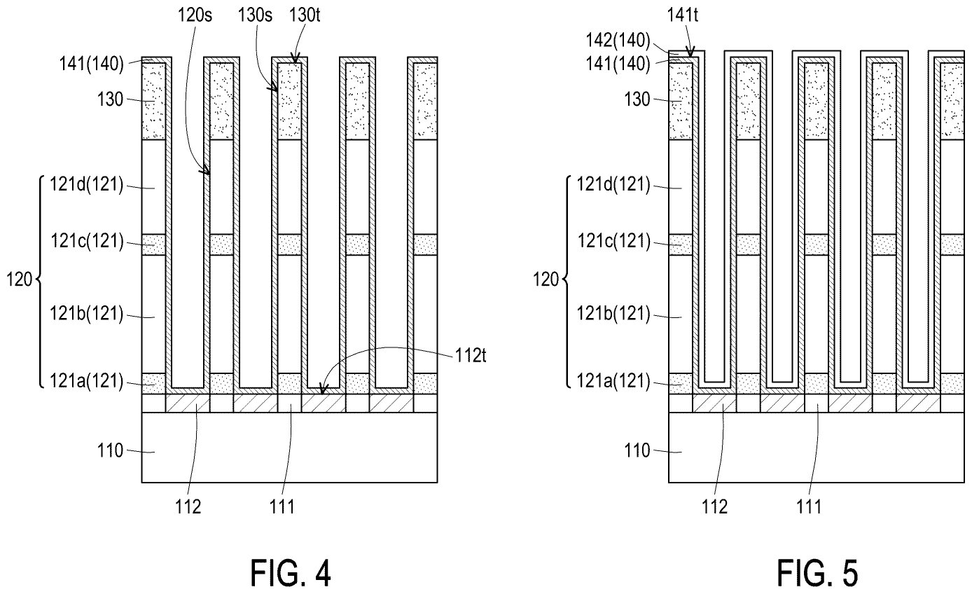

At block 105, form an electrode structure over the substrate. FIG. 4 to FIG. 6 illustrate cross-sectional views of some embodiments corresponding to block 105.

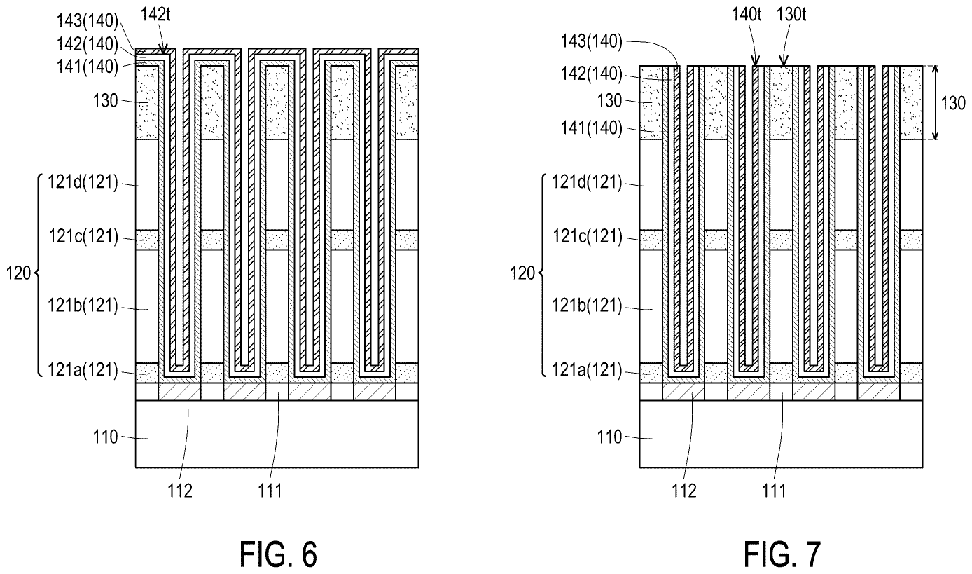

In one embodiment, as shown in FIG. 4 to FIG. 6, form an electrode structure 140 in double site over the substrate 110, that is to say, the electrode structure 140 is composed of two conductive layers 141, 143 and one dielectric layer 142 interposed between the two conductive layers 141, 143. The electrode structure 140 is formed as follow. In FIG. 4, the conductive layer 141 is conformally formed over the substrate 110, therefore, the conductive layer 141 covers top surfaces 112t of the landing pads 112, sidewalls 120s of the first insulating structure 120, sidewalls 130s of the patterned mask layer 130, and a top surface 130t of the patterned mask layer 130, wherein the conductive layer 141 may be referred to a top electrode. In the embodiment, the conductive layer 141 is direct in contact with the landing pads 112 and electrically connected thereof. In FIG. 5, the dielectric layer 142 is conformally formed over the substrate 110. For example, a top surface 141t of the conductive layer 141 is covered by the dielectric layer 142. In FIG. 6, the conductive layer 143 is conformally formed over the substrate 110. For example, a top surface 142t of the dielectric layer 142 is covered by the conductive layer 143, wherein the conductive layer 143 may be referred to a bottom electrode. In the embodiment, the electrode structure 140 is not filled up the containers 10 in FIG. 3.

In the embodiment, the nitride layer 121a is disposed beside and in direct contact with a bottom portion of the electrode structure 140 (may be within position of one-third of the electrode structure 140) to enforce the structural strength of the electrode structure 140. In addition, the nitride layer 121c is disposed beside and in direct contact with a middle portion of the electrode structure 140 (may be within position of one-third to two-third of the electrode structure 140) to further enforce the structural strength of the electrode structure 140.

In some embodiments, material of the conductive layer 141 includes TiN, or the like. In some embodiments, material of the dielectric layer 142 includes suitable high-k dielectric materials. In some embodiments, material of the conductive layer 143 includes TiN, or the like. Here, the conductive layers 141, 143 and the dielectric layer 142 may be form by suitable deposition processes, such as blanket deposition, chemical vapor deposition (CVD), physical vapor deposition (PVD), atomic layer deposition (ALD), or the like.

At block 106, remove a first portion of the electrode structure by a first etching back process. FIG. 6 and FIG. 7 illustrate cross-sectional views of some embodiments corresponding to block 106.

In FIG. 6, the electrode structure 140 includes a first portion disposed on the patterned mask layer 130 and a second portion disposed in the containers 10, and then, in FIG. 7, a first portion disposed on the patterned mask layer 130 may be removed by a first etching back process. For example, etching gases of the first etching back process may include Cl, BCl₃, and Ar, with high etching selectivity ratio between the patterned mask layer 130 and the electrode structure 140, by doing so, the first portion of the electrode structure 140 may be easily to remove. In some embodiments, when Cl, BCl₃, Ar all used in the first etching back process, the ratio may be 3:1:1, but the disclosure is not limited to, other suitable value may be used. After the first etching back process, a top surface 140t of the electrode structure 140 and a top surface 130t of the patterned mask layer 130 are substantially coplanar. In the embodiment, the patterned mask layer 130 may be slightly removed by the first etching back process. For example, a height 130H of the patterned mask layer 130 in step of FIG. 7 may become about 80 nm or other suitable value less than a height 130H of the patterned mask layer 130 in step of FIG. 6.

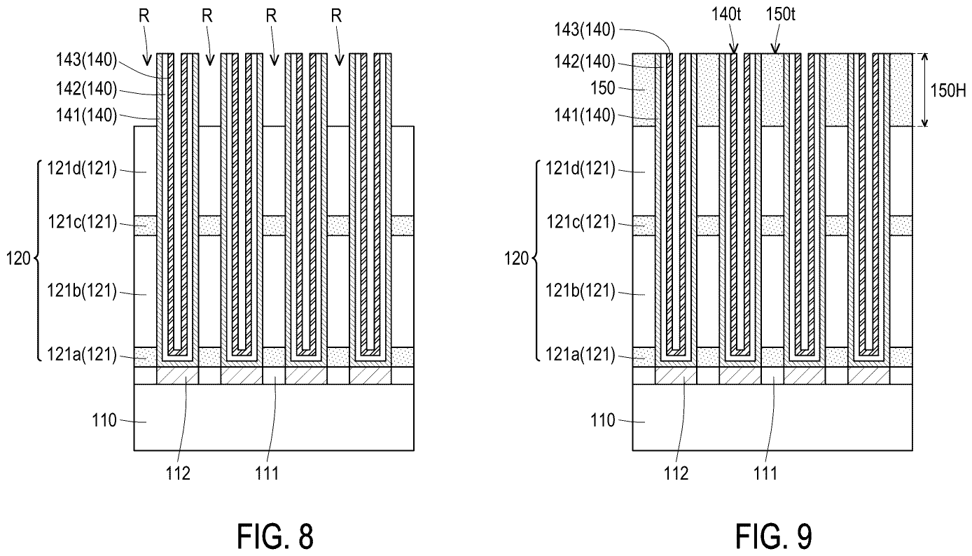

At block 107, remove the patterned mask layer by a second etching back process to form recesses on the first insulating structure and beside a second portion of the electrode structure. FIG. 8 illustrates a cross-sectional view of some embodiments corresponding to block 107.

In FIG. 8, etching gases of the second etching back process may include Cl and CF₄, and the recesses R may be formed by high etching selectivity ratio between the patterned mask layer 130 and the electrode structure 140, by doing so, the patterned mask layer 130 may be easily to remove. In some embodiments, when Cl and CF₄ all used in the second etching back process, and the ratio may be 3:1, but the disclosure is not limited to, other suitable value may be used.

At block 108, form a second insulating structure in the recesses. FIG. 9 illustrates a cross-sectional view of some embodiments corresponding to block 108.

In FIG. 9, a nitride material is deposited and filled up the recesses R to form an insulating structure 150 (may be referred to second insulating structure). In the embodiment, the insulating structure 150 may overall cover the electrode structure 140 at first (not shown), and then removed by another etching back process, such that a top surface 140t of the electrode structure 140 and a top surface 150t of the insulating structure 150 are substantially coplanar. Further, a height 150H of the insulating structure 150 is greater than the height Ha of the nitride layer 121a or the height Hc of the nitride layer 121c. Moreover, the insulating structure 150 is disposed beside and in direct contact with a top portion of the electrode structure 140 to enforce the structural strength of the electrode structure 140.

After FIG. 9, other suitable processes may be performed to produce a capacitor. For example, the steps of FIG. 2 to FIG. 9 may be performed repeatedly(not shown). In addition, the insulating structure 120 and the insulating structure 150 may be removed (not shown) depended on the actual design requirement. It should be noted that the scope of the present application is not limited to the specific embodiments of the process, machine, manufacture, composition of matter, means, methods and steps described in the specification. Those skilled in the art can understand from the disclosure content of this disclosure that existing or future developed processes, machinery, manufacturing, A composition of matter, means, method, or step. Accordingly, such process, machinery, manufacture, material composition, means, method, or steps are included in the patent scope of this application.

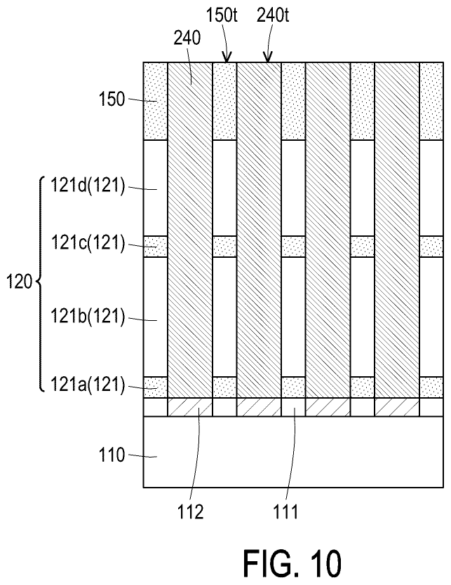

Referring to FIG. 10, the memory device in FIG. 10 includes the substrate 110, the isolation layer 111, the landing pads 112, the insulating structure 120, the second insulating structure 150, and electrode structure 240, wherein the structures of the substrate 110, the isolation layer 111, the landing pads 112, the insulating structure 120, the second insulating structure 150 may be similar to the aforementioned embodiment and are not reiterated here. The electrode structure 240 of the memory device in present embodiment is different from the electrode structure 140 of the aforementioned embodiment. For example, the electrode structure 240 is composed of one conductive layer (single site), and the electrode structure 240 is filled up the container 10. In the embodiment, a top surface 240t of the electrode structure 240 and a top surface 150t of the second insulating structure 150 are substantially coplanar.

In the present disclosure, the height (such as an etching height 120H of the insulating structure 120) of the container 10 may be reduced and the remaining required height of capacitor of in memory device may be achieved by at least twice etching back processes and backfill another insulating layer (such as the insulating structure 150), by doing so, the height of the container 10 may be designed flexibly, thereby the high-aspect-ratio may be improved. Further, quality of the container 10 may be increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a memory device, comprising:
forming a landing pad over a substrate;
forming a first insulating structure over the substrate and the landing pad;
forming a patterned mask layer over the insulating structure;
removing portions of the first insulating structure by the patterned mask layer to form a container exposing the landing pad;
forming an electrode structure over the substrate, wherein the electrode structure comprises a first portion disposed on the patterned mask layer and a second portion disposed in the container;
removing the first portion of the electrode structure by a first etching back process;
removing the patterned mask layer by a second etching back process to form recesses on the first insulating structure and beside the second portion of the electrode structure; and
forming a second insulating structure in the recesses.

2. The manufacturing method of a memory device as claimed in claim 1, wherein aspect ratio of the container range between 30 and 40.

3. The manufacturing method of a memory device as claimed in claim 1, wherein etching gases of the first etching back process comprise Cl, BCl₃, and Ar.

4. The manufacturing method of a memory device as claimed in claim 1, wherein etching gases of the second etching back process comprise Cl and CF₄.

5. The manufacturing method of a memory device as claimed in claim 1, wherein forming a second insulating structure in the recesses comprises depositing a nitride material to fill up the recesses.

6. The manufacturing method of a memory device as claimed in claim 1, wherein materials of the patterned mask layer comprise polysilicon.

7. The manufacturing method of a memory device as claimed in claim 1, wherein a top surface of the first insulating structure is in direct contact with a bottom surface of the patterned mask layer.

8. The manufacturing method of a memory device as claimed in claim 1, wherein after the first etching back process, a top surface of the electrode structure and a top surface of the patterned mask layer are coplanar.

9. The manufacturing method of a memory device as claimed in claim 1, wherein a top surface of the electrode structure and a top surface of the second insulating structure are coplanar.

10. The manufacturing method of a memory device as claimed in claim 1, wherein a height of the first insulating structure ranges between 1000 nm to 1300 nm.

11. The manufacturing method of a memory device as claimed in claim 1, wherein a width of the container is less than or equal to a width of the landing pad.

12. The manufacturing method of a memory device as claimed in claim 1, wherein the first insulating structure comprises a first nitride layer disposed on the substrate and a first oxide layer disposed on the first nitride layer.

13. The manufacturing method of a memory device as claimed in claim 12, wherein the first nitride layer is disposed beside and in direct contact with a bottom portion of the electrode structure.

14. The manufacturing method of a memory device as claimed in claim 12, wherein a height of the first oxide layer is greater than a height of the first nitride layer.

15. The manufacturing method of a memory device as claimed in claim 12, wherein a height of the second insulating structure is greater than a height of the first nitride layer.

16. The manufacturing method of a memory device as claimed in claim 12, wherein a height o f the first nitride layer ranges between 20 nm and 30 nm.

17. The manufacturing method of a memory device as claimed in claim 12, wherein the first insulating structure further comprises a second nitride layer disposed on the first oxide layer and a second oxide layer disposed on the second nitride layer.

18. The manufacturing method of a memory device as claimed in claim 17, wherein the second nitride layer is disposed beside and in direct contact with a middle portion of the electrode structure.

19. The manufacturing method of a memory device as claimed in claim 1, wherein the electrode structure is composed of two conductive layers and one dielectric layer interposed between the two conductive layers, and the electrode structure is conformally formed over the substrate.

20. The manufacturing method of a memory device as claimed in claim 1, wherein the electrode structure is composed of one conductive layer, and the electrode structure is filled up the container.
